(19) United States
(12) Patent Application Publication
(10) Pub. No.: US 2025/0357914 A1
(43) Pub. Date: Nov. 20, 2025

(54) SURFACE ACOUSTIC WAVE DEVICE HAVING AN ELECTRODE STRUCTURE WITH IMPROVED NONLINEARITY, FILTER INCLUDING THE SAME, AND METHOD FOR MANUFACTURING THE SURFACE ACOUSTIC WAVE DEVICE

(71) Applicant: WISOL CO., LTD., Osan-si (KR)

(72) Inventors: Yoshikazu KIHARA, Osan-si (KR); Sang Hoon MYEONG, Osan-si (KR); Ki Jung LEE, Osan-si (KR)

(73) Assignee: WISOL CO., LTD., Osan-si (KR)

(21) Appl. No.: 19/190,297

(22) Filed: Apr. 25, 2025

(30) Foreign Application Priority Data
May 17, 2024 (KR) 10-2024-0064697

(51) Int. Cl. H03H 9/25; H03H 3/08; H03H 9/145; H03H 9/64

(52) U.S. Cl. CPC H03H 9/25; H03H 3/08; H03H 9/145; H03H 9/6483

(57) ABSTRACT

A surface acoustic wave device having an electrode structure with improved nonlinearity, a filter including the same, and a method for manufacturing the surface acoustic wave device are provided. The surface acoustic wave device comprises a piezoelectric substrate and a plurality of IDT electrodes formed on the piezoelectric substrate, wherein each of the plurality of IDT electrodes comprises a lower electrode formed on a surface of the piezoelectric substrate and an upper electrode formed on the lower electrode, and wherein the lower electrode has a hardness of 12 GPa to 16 GPa.

### FIELD OF THE INVENTION

The present invention relates to a surface acoustic wave (SAW) device having an electrode structure with improved nonlinearity, a filter comprising the same, and a method for manufacturing the surface acoustic wave device. More specifically, it concerns a surface acoustic wave device with enhanced nonlinearity through a stacked (dual-structure) interdigital transducer (IDT) electrode, which includes a lower electrode with high elasticity and hardness, and a method for manufacturing a surface acoustic wave (SAW) device with improved operating characteristics due to the reduction of higher-order signal components through the improved nonlinearity.

### BACKGROUND OF RELATED ART

The surface acoustic wave (SAW) refers to waves that propagate along the surface of an elastic solid. These surface acoustic waves concentrate their energy near the surface as they propagate and are considered mechanical waves. A surface acoustic wave device is an electromechanical device that utilizes the interaction between these surface acoustic waves and conductive electrons, making use of surface acoustic waves transmitted on the surface of a piezoelectric crystal. These surface acoustic wave devices have a broad industrial application, including sensors, oscillators, and filters, and they offer various advantages such as miniaturization, lightweight, durability, stability, sensitivity, low cost, and real-time functionality.

SAW filters used in communication circuits supporting the 5G communication standard require high nonlinearity. However, with the introduction of Carrier Aggregation (CA) on the Tx side in the 5G communication standard, two or more Tx signals with high signal levels are input to a SAW filter with nonlinearity, potentially causing larger unwanted signals due to intermodulation. Therefore, to reduce unnecessary signals caused by intermodulation, it is necessary to improve the nonlinearity of the SAW resonator and reduce the higher-order signal components.

Various methods have been proposed to improve the nonlinearity of SAW filters, which can be broadly categorized into circuit-based approaches and material-based approaches. The circuit-based approach reduces the level of nonlinear signals by lowering the signal level and voltage input to the SAW resonator. For example, increasing the size of the SAW resonator, lowering the impedance, or configuring multi-stage connections of the resonator can help lower the voltage applied to a single resonator.

On the other hand, there have been ongoing attempts to improve nonlinearity by appropriately adjusting the structure and materials of the IDT electrodes included in the SAW resonator.

### DISCLOSURE OF THE INVENTION

### Technical Problem

The technical problem to be solved by the present invention is to provide a surface acoustic wave (SAW) device with improved nonlinearity through a dual-structure IDT electrode having a lower electrode with high elasticity and hardness, and a filter with improved operating characteristics through the reduction of higher-order signal components, along with methods for manufacturing these devices.

### Technical Solution

The surface acoustic wave (SAW) device with improved nonlinearity according to an embodiment of the present invention to solve the aforementioned technical problem includes a piezoelectric substrate and a plurality of IDT electrodes formed on the piezoelectric substrate. Each of the plurality of IDT electrodes includes a lower electrode formed on the surface of the piezoelectric substrate, and an upper electrode formed on the lower electrode, where the hardness of the lower electrode is between 12 GPa and 16 GPa.

In some embodiments of the present invention, the lower electrode may include tungsten or chromium, and the upper electrode may include an aluminum-copper alloy.

In some embodiments of the present invention, the thickness of the lower electrode may be between 5 nm and 20 nm.

In some embodiments of the present invention, the elasticity modulus of the lower electrode may be greater than or equal to 320 GPa.

In some embodiments of the present invention, the structure may further include a bonding enhancement layer interposed between the lower electrode and the piezoelectric substrate.

In some embodiments of the present invention, the thickness of the bonding enhancement layer may be smaller than the thickness of the lower electrode.

A filter according to an embodiment of the present invention, which includes a surface acoustic wave (SAW) device to solve the aforementioned technical problem, comprises a transmission circuit and a reception circuit. The transmission circuit includes a first SAW resonator, and the reception circuit includes a second SAW resonator. The first SAW resonator includes a plurality of first IDT electrodes, and the second SAW resonator includes a plurality of second IDT electrodes. Each of the plurality of first IDT electrodes includes a lower electrode formed on the surface of a piezoelectric substrate, and an upper electrode formed on the lower electrode, wherein the hardness of the lower electrode is between 12 GPa and 16 GPa.

A method for manufacturing a surface acoustic wave (SAW) device with an improved electrode structure to solve the aforementioned technical problem according to an embodiment of the present invention includes the steps of: preparing a piezoelectric substrate; forming a lower electrode film on the piezoelectric substrate; forming an upper electrode film on the lower electrode film; and forming a plurality of IDT electrodes including the lower electrode and the upper electrode, wherein the hardness of the lower electrode is between 12 GPa and 16 GPa.

### Effects of the Invention

The surface acoustic wave (SAW) device with an improved electrode structure according to the present invention has a lower electrode that includes tungsten or chromium with high hardness and elasticity, thereby having a higher plastic deformation limit. As a result, it can have a wider elastic deformation range and improved nonlinearity.

### DESCRIPTION OF DRAWINGS

FIG. 1 is a top view of the surface acoustic wave (SAW) device with the improved nonlinear electrode structure according to one embodiment of the present invention.

FIGS. 2A and 2B are cross-sectional views taken along line A-A′ in FIG. 1.

FIGS. 3A and 3B are diagrams illustrating the effects of the improved nonlinear electrode structure of the SAW device according to one embodiment of the present invention.

FIGS. 4A and 4B are diagrams showing the changes in the second-order and third-order nonlinearities as a function of the thickness of the lower electrode.

FIGS. 5A and 5B are results showing the change in insertion loss as a function of the thickness of the lower electrode in the SAW device according to one embodiment of the present invention.

FIGS. 6A and 6B are diagrams comparing the hardness and elastic modulus of tungsten in the SAW device with titanium or aluminum-copper alloy, according to one embodiment of the present invention.

FIGS. 7A and 7B are diagrams illustrating the relationship between the hardness of the lower electrode and the second-order and third-order nonlinearities.

FIGS. 8A and 8B show a comparison of the shear strain calculation results using the SAW device of the prior art and the SAW device according to one embodiment of the present invention.

FIGS. 9A and 9B are diagrams explaining the improved nonlinear electrode structure of the SAW device according to another embodiment of the present invention.

FIGS. 10 to 11B show a filter comprising the SAW device with the improved nonlinear electrode structure according to one embodiment of the present invention.

FIG. 12 is a flowchart illustrating the manufacturing method of the SAW device with the improved nonlinear electrode structure according to one embodiment of the present invention.

### EMBODIMENTS OF THE INVENTION

The advantages and features of the present invention and the method for achieving them will become clear by referring to the embodiments described below in detail together with the accompanying drawings. However, the present invention is not limited to the embodiments disclosed below and will be implemented in various different forms. These embodiments are provided only to make the disclosure of the present invention complete and to fully inform those skilled in the art of the scope of the present invention, and the present invention is only defined by the scope of the claims. Like reference numerals refer to like elements throughout the specification.

“And/or” includes each of the mentioned items and all combinations of one or more of the mentioned items.

The terms used in this specification are to describe the embodiments and are not to limit the present invention. In this specification, singular forms also include plural forms unless specially stated otherwise in the phrases. The terms “comprises” and/or “comprising” used in this specification means that the mentioned components, steps, operations, and/or elements do not exclude the presence or addition of one or more other components, steps, operations and/or elements.

In addition, throughout the specification, when a part is said to be “connected” to another part, this also includes “indirectly” or “electrically connected” cases with intervention of other members or components therebetween, as well as “directly connected” cases.

In addition, throughout the specification, the description that each layer (film), region, pattern, or structure is formed “above/on” or “beneath/under” a substrate, each layer (film), region, pad, or pattern includes both cases that they are formed directly and formed with intervention of other layers. The criteria for being above/on or beneath/under each layer are explained with reference to the drawings.

In addition, expressions such as ‘first, second’, and the like are only used to distinguish a plurality of components, and do not limit the sequence of the components or other features.

In addition, the flowcharts shown in the drawings merely illustrate an exemplary sequence for achieving the most desirable results in implementing the present invention. It is understood that additional steps may be added or certain steps may be omitted as necessary.

Unless defined otherwise, all the terms (including technical and scientific terms) used in this specification may be used as meanings that can be commonly understood by those skilled in the art. In addition, terms defined in commonly used dictionaries are not interpreted ideally or excessively unless clearly and specifically defined.

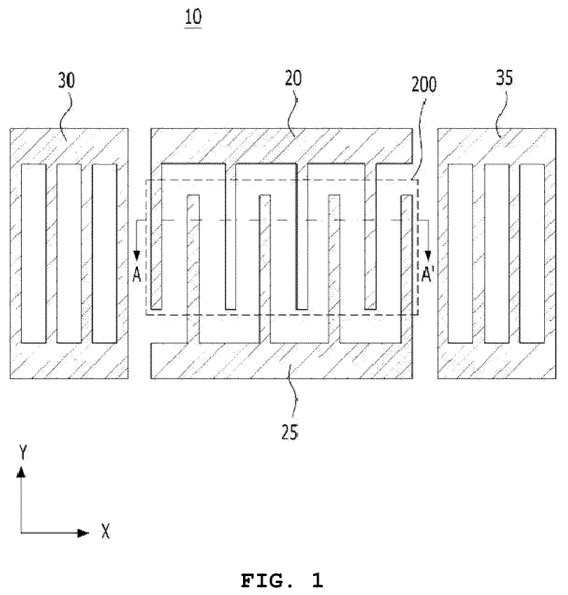

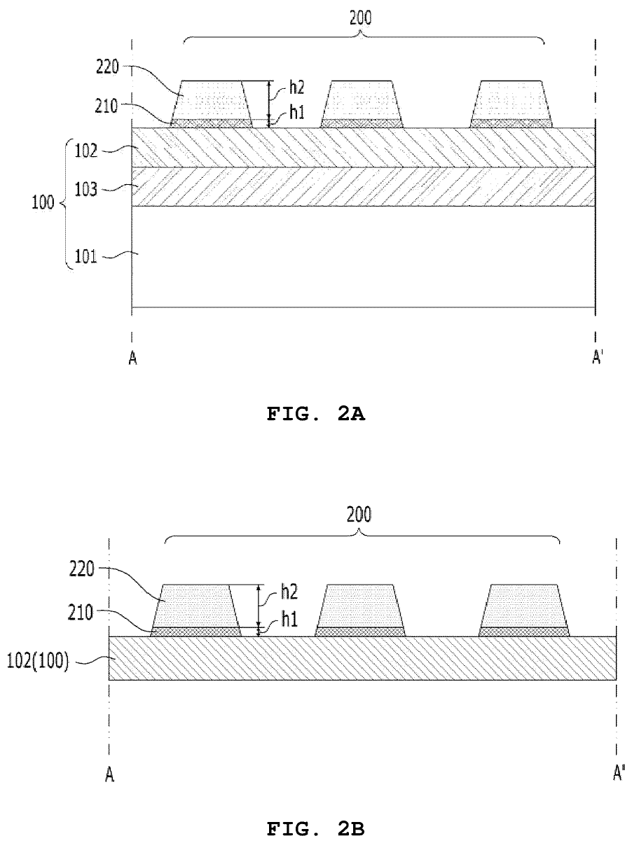

FIG. 1 is a top view of the surface acoustic wave (SAW) device with the improved nonlinear electrode structure according to one embodiment of the present invention, and FIGS. 2A and 2B are cross-sectional views taken along line A-A′ of FIG. 1.

Referring to FIG. 1, the surface acoustic wave device 10 according to an embodiment of the present invention, which has an improved nonlinear electrode structure, may include a surface acoustic wave resonator with a first busbar 20 and a second busbar 25 extending in parallel in a first direction X, and a plurality of IDT electrodes 200 alternately extending in a second direction Y from the first and second busbars 20, 25. Reflectors 30, 35 may be disposed on both sides of the surface acoustic wave resonator.

Specifically, referring to FIG. 2A, the surface acoustic wave device 10 according to an embodiment of the present invention, which has an improved nonlinear electrode structure, may include a piezoelectric substrate 100 and a plurality of IDT electrodes 200 formed on the piezoelectric substrate 100.

The piezoelectric substrate 100 may have a structure in which a plurality of substrates are stacked, and more specifically, it may have a structure in which a piezoelectric layer 102 is stacked on a supporting substrate 101. Of course, the structure of the piezoelectric substrate 100 in FIG. 2A is exemplary, and the piezoelectric substrate 100 is not excluded from being configured as a single structure of the piezoelectric layer 102, with or without the supporting substrate 101 and/or the insert layer 103, as shown in FIG. 2B.

The supporting substrate 101 may be composed of semiconductor substrates such as silicon, as well as ceramic substrates, insulating substrates, and the like.

The piezoelectric layer 102 includes a piezoelectric material and can generate an acoustic wave from the signal applied to the IDT electrode 200. It may include materials such as LiTaO3 (LT), LiNbO3 (LN), and the like.

When the piezoelectric layer 102 includes an LT substrate, the cut angle may range from 36° Y to 50° Y, and the elastic surface wave in this case is an SH (Shear Horizontal) wave. Additionally, when the piezoelectric layer 102 includes an LN substrate, the cut angle may range from 0° Y to 64° Y, and the elastic surface wave in this case is also an SH wave.

In some embodiments of the present invention, as shown in FIG. 2, the piezoelectric substrate 100 may include an insert layer 103 interposed between the support substrate 101 and the piezoelectric layer 102. The insert layer 103 may be a layer that transmits a lower or higher sound speed than the elastic wave propagated by the piezoelectric layer 102. Therefore, a low-speed layer that transmits a sound speed lower than that of the surface acoustic wave may be interposed between the support substrate 101 and the piezoelectric layer 102, or a high-speed layer that transmits a sound speed higher than that of the surface acoustic wave may be inserted between the support substrate 101 and the piezoelectric layer 102. Additionally, in some embodiments, a low-speed layer may be stacked on top of a high-speed layer to trap the elastic wave at the surface of the high-speed layer.

A plurality of IDT electrodes 200 may be formed on the upper surface of the piezoelectric substrate 100, specifically on the piezoelectric layer 102. The plurality of IDT electrodes 200 may be formed in a dual structure of a lower electrode 210 and an upper electrode 220.

Each of the plurality of IDT electrodes 200 may have a tapered shape, where the width narrows as it extends upward from the surface of the piezoelectric substrate 100. At this time, the width of the upper surface of the lower electrode 210 and the lower surface of the upper electrode 220, which are in contact with each other, may be the same.

The lower electrode 210 may include, for example, tungsten (W), and the upper electrode 220 may include either aluminum (Al) or copper (Cu), or an alloy of these metals. In the surface acoustic wave device 10 according to one embodiment of the present invention, the inclusion of tungsten (W) in the lower electrode 210 is intended to take advantage of the properties derived from the hardness and elastic modulus of tungsten (W).

On the other hand, in some embodiments of the present invention, the lower electrode 210 may include tungsten (W) along with trace amounts of tungsten carbide (WC) formed by a chemical reaction with carbon, tungsten nitride (WN) with added nitrogen, tungsten oxide (WO) with added oxygen, and other tungsten alloys primarily composed of tungsten.

Meanwhile, there is about a 7-fold density difference between the aluminum included in the upper electrode 220 and the tungsten included in the lower electrode, which can result in a greater mass loading effect when a signal is applied to the lower and upper electrodes 210, 220, compared to the case where titanium (Ti) is used as the lower electrode. This can also cause the speed of the surface acoustic wave to decrease further. The electrical resistivity of tungsten (W) is lower than that of titanium (Ti), so when the lower electrode 210 has the same thickness, it is possible to reduce the electrical resistance of each of the multiple IDT electrodes 200, thereby improving the electrical characteristics of the surface acoustic wave device 10.

The thickness (h1) of the lower electrode 210 may be smaller than the thickness (h2) of the upper electrode 220. Specifically, the thickness (h1) of the lower electrode 210 may range from 5 nm to 20 nm.

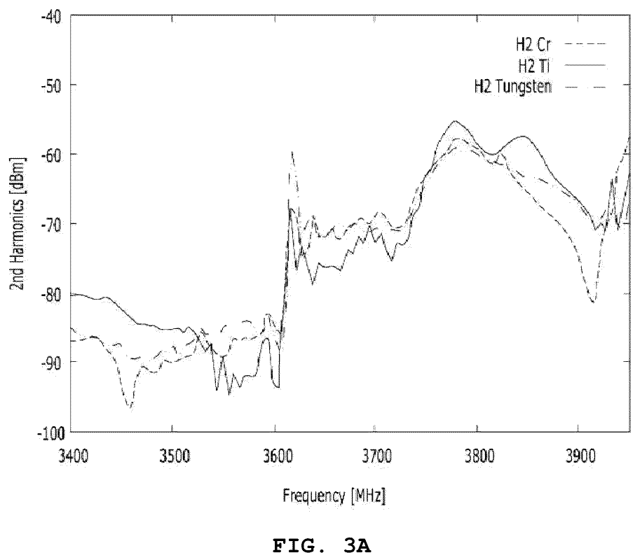

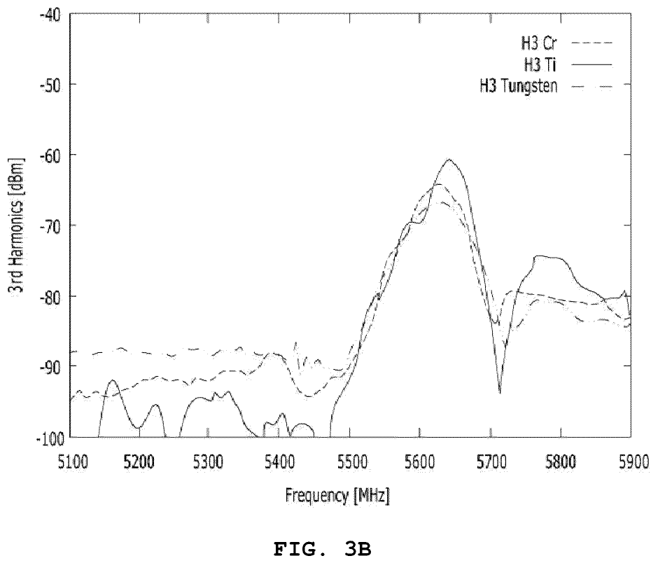

FIG. 3A and FIG. 3B are diagrams explaining the effects of the surface acoustic wave device with improved nonlinear electrode structure according to an embodiment of the present invention.

Referring to FIG. 3A and FIG. 3B, graphs comparing the second-order nonlinear characteristics (FIG. 3A) and third-order nonlinear characteristics (FIG. 3B) of the surface acoustic wave device according to an embodiment of the present invention with those of the surface acoustic wave device according to the prior art are shown. In the surface acoustic wave device according to the prior art, the lower electrode 210 includes titanium (Ti), and the upper electrode 220 contains the same aluminum and copper alloy as in the present invention.

Referring to FIG. 3A and FIG. 3B, the resonator that includes the surface acoustic wave device used has a resonant frequency of approximately 1800 MHz and an anti-resonant frequency of 1900 MHZ, with the second-order and third-order nonlinear signals occurring most strongly at twice and three times the anti-resonant frequency, respectively. The smaller levels of the second-order and third-order nonlinear signals in FIG. 3A and FIG. 3B indicate that the device exhibits favorable nonlinear characteristics.

Compared to the conventional electrode structure, the surface acoustic wave device with chromium included in the lower electrode primarily reduces the harmonic levels at the 3800 MHz band, which is twice the frequency, while the surface acoustic wave device with tungsten included reduces the harmonic levels at both the 3800 MHz and 5700 MHz bands, which correspond to the second and third harmonic frequencies, respectively.

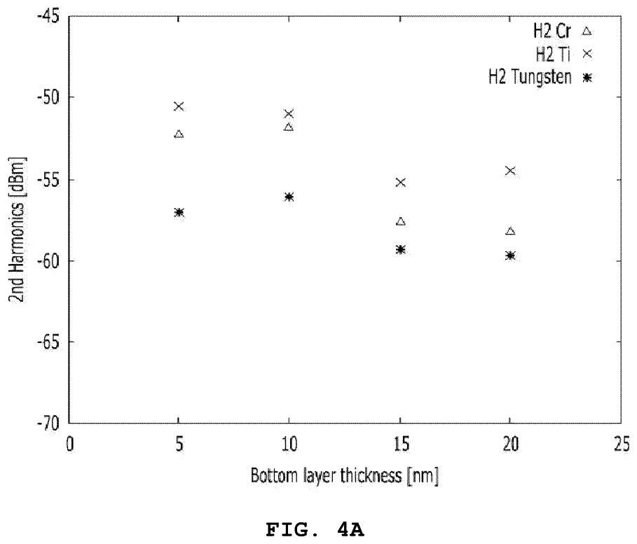

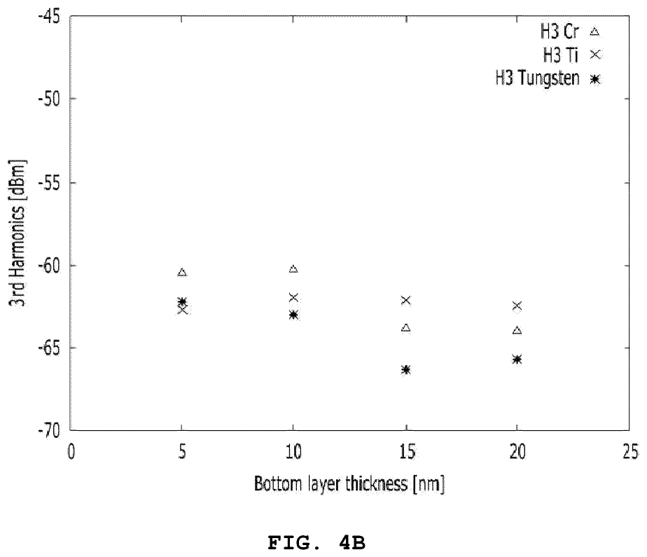

Additionally, the results measuring the changes in second-order nonlinearity and third-order nonlinearity due to variations in the thickness h1 of the lower electrode are shown in FIGS. 4A and 4B, respectively.

Referring to FIG. 4A and FIG. 4B, graphs comparing the second-order nonlinearity (FIG. 4A) and third-order nonlinearity (FIG. 4B) of the surface acoustic wave device according to an embodiment of the present invention with those of a surface acoustic wave device according to the prior art are shown, when the thickness h1 of the lower electrode is varied. The surface acoustic wave device according to the prior art includes a lower electrode (210) made of titanium (Ti), and the upper electrode (220) includes an aluminum-copper alloy, similar to the present invention. All surface acoustic wave devices were set to have the same anti-resonant frequency and impedance.

When compared to the conventional electrode structure, the surface acoustic wave device with chromium in the lower electrode shows a slight reduction in third-order nonlinearity but an improvement in second-order nonlinearity. The surface acoustic wave device with tungsten in the lower electrode shows a significant improvement in second-order nonlinearity and an improvement in third-order nonlinearity as well. In embodiments of the present invention, when the surface acoustic wave device includes chromium or tungsten, it is observed that as the thickness of the lower electrode (210) increases, the second-order nonlinearity improves. The degree of improvement in nonlinearity due to the thickness of the lower electrode tends to saturate around 20 nm.

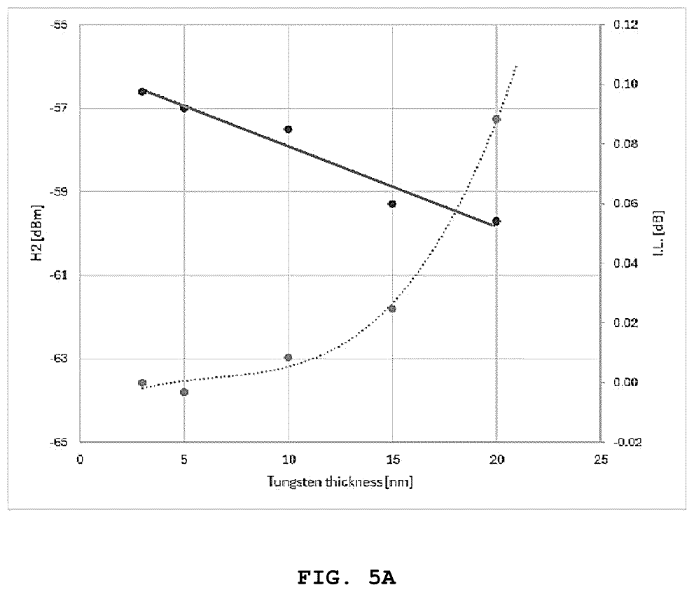

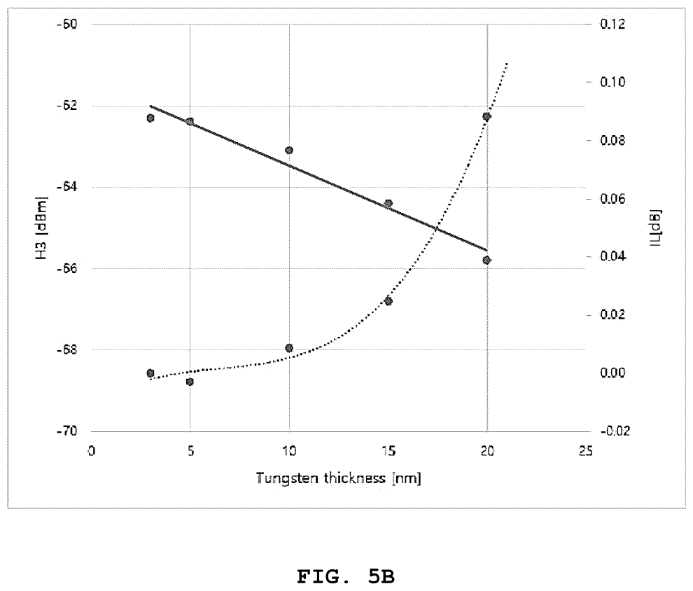

FIG. 5A and FIG. 5B show the results of measuring the change in insertion loss due to the variation in the thickness of the lower electrode in the surface acoustic wave device according to an embodiment of the present invention.

Referring to FIG. 5A and FIG. 5B, the results of constructing a 1-stage ladder filter using the surface acoustic wave device according to an embodiment of the present invention are shown. The signal levels of the second-order harmonics (solid line graph in FIG. 5A) and insertion loss (dashed line graph in FIG. 5A), as well as the signal levels of the third-order harmonics (solid line graph in FIG. 5B) and insertion loss (dashed line graph in FIG. 5B), are measured and presented.

As observed earlier, increasing the thickness of the lower electrode 210 improves the nonlinearity, but also increases the insertion loss of the filter. If the insertion loss allowed for a single-stage filter is defined as 0.1 dB, the thickness of the lower electrode 210 may be less than or equal to 20 nm. Considering the lower limit of the film thickness that can actually be deposited, the thickness of the lower electrode 210 is preferably at least 2 nm.

When an alternating current signal is applied to the surface acoustic wave device, an elastic surface wave is generated by the plurality of IDT electrodes 200, and periodic deformation occurs in each of the IDT electrodes. The region where the material deforms linearly under the applied force is referred to as the elastic deformation region, while the region showing nonlinear deformation is referred to as the plastic deformation region.

When the deformation of the IDT electrodes is in the small elastic deformation region, it is assumed that the deformation occurs linearly with respect to the applied force, and no nonlinear signal based on mechanical deformation is generated from the IDT electrodes. However, as the input signal increases, the amplitude of the surface acoustic wave increases, and the deformation of the IDT electrodes also increases. This leads to oscillation in regions close to the plastic deformation region of the material, initiating operation in the nonlinear region.

Therefore, as explained earlier, to improve the operation of the IDT electrodes in the nonlinear region, it is necessary to suppress the mechanical deformation of the IDT electrodes. This can be achieved by keeping the deformation amount small or by maximizing the range of elastic deformation of the IDT electrodes.

In the past, when forming the IDT electrodes with an alloy of aluminum and copper, titanium was used as the lower electrode to improve the contactability with the underlying piezoelectric substrate. In contrast, in the surface acoustic wave device according to an embodiment of the present invention, as previously described, to increase the range of elastic deformation of the IDT electrodes, a material with high hardness and high elasticity, such as tungsten or chromium, or an alloy comprising one of these, may be used as the lower electrode 210.

As is well known, plastic deformation refers to the range of deformation that does not return to its original shape after the material has been deformed, and the hardness, such as Vickers hardness, Brinell hardness, and Rockwell hardness, is defined to quantify the ease of plastic deformation. The ease of reversible deformation of a material can be represented by its elastic modulus, or Young's modulus. For coating materials, nanoindentation is often used. Nanoindentation is a method similar to Vickers hardness measurement and is used to measure the hardness and elastic modulus of thin film materials.

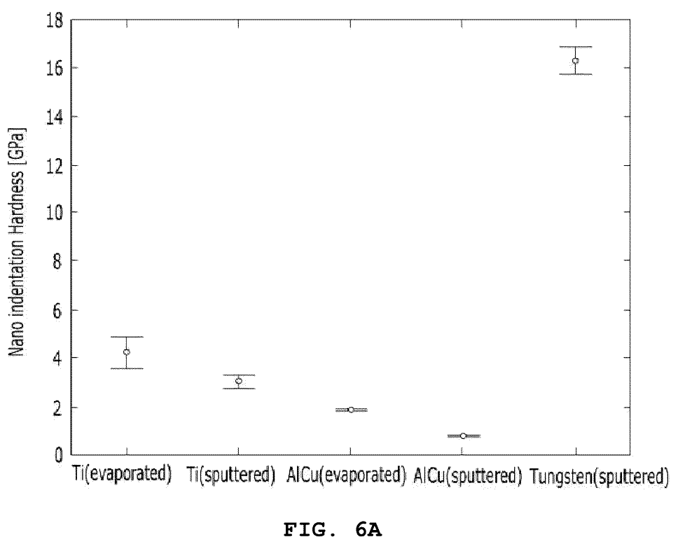

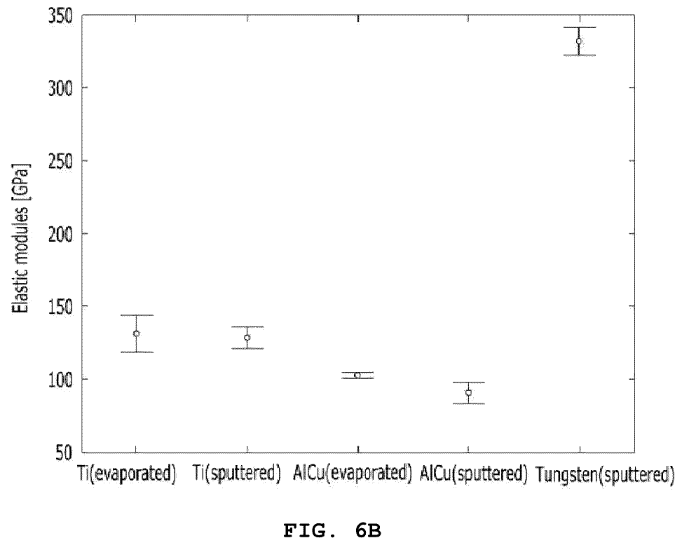

FIG. 6A and FIG. 6B are diagrams comparing the hardness and elastic modulus of tungsten included in the surface acoustic wave device according to an embodiment of the present invention with titanium or aluminum-copper alloys.

Referring to FIG. 6A, a comparison of the hardness between titanium or aluminum-copper alloys formed on a silicon substrate and tungsten, as in the present invention, is shown. The comparative examples of titanium or aluminum-copper alloys display results from sputtering or deposition processes, and the hardness and elastic modulus are measured by nano-indentation testing. Titanium has about twice the hardness of aluminum-copper alloys, but tungsten has a much higher hardness of approximately 16 GPa or more. Similarly, in FIG. 6B, the elastic modulus of titanium is measured to be approximately 130 GPa, which is about 1.3 times higher than that of aluminum-copper alloys, while tungsten shows a much higher elastic modulus of over 320 GPa, more than three times higher.

As such, in the surface acoustic wave device 10 according to an embodiment of the present invention, the lower electrode 210 includes tungsten or chromium, which has higher hardness and elastic modulus than titanium Ti. This provides a higher plastic deformation limit than titanium Ti, thereby enabling a wider elastic deformation range and improving nonlinearity.

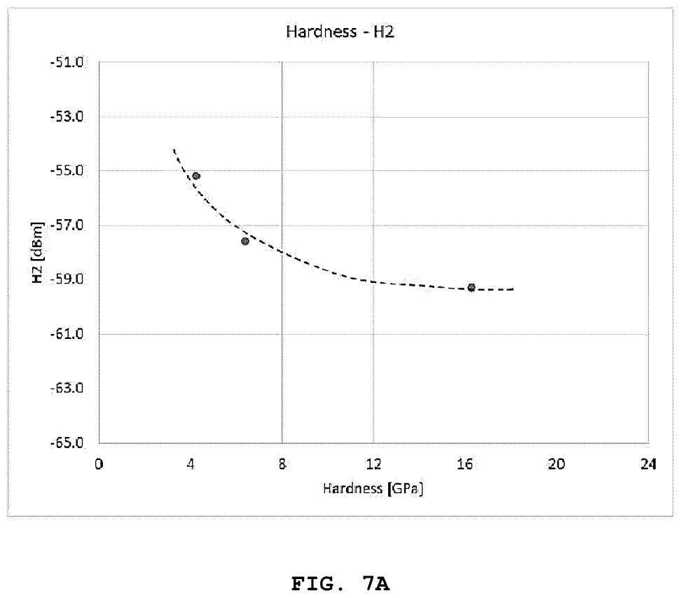

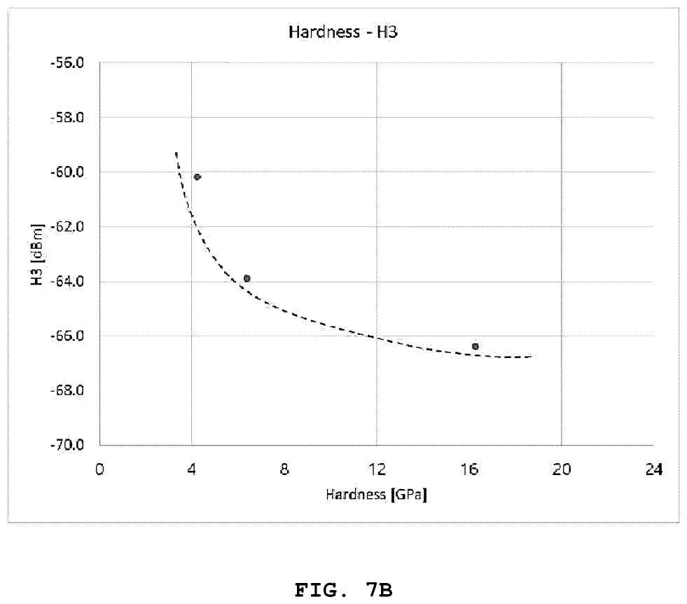

FIG. 7A and FIG. 7B are diagrams illustrating the relationship between the hardness of the lower electrode and the second-and third-order nonlinearities.

Referring to FIG. 7A and FIG. 7B, the change in the signal levels of the harmonics generated by the second-and third-order nonlinearities is measured under the same conditions as the results in FIG. 3A through 4B. In each case, when the hardness is about 12 GPa, the second-order harmonic level is 59 dBm, and the third-order harmonic level is 66 dBm, confirming a significant improvement in nonlinearity. It can also be seen that the improvement in nonlinearity diminishes when the hardness exceeds 16 GPa. Furthermore, comparing this with the elasticity modulus of the lower electrode (210) containing tungsten in FIG. 6B, it can be predicted that the improvement in nonlinearity diminishes when the elasticity modulus exceeds 320 GPa.

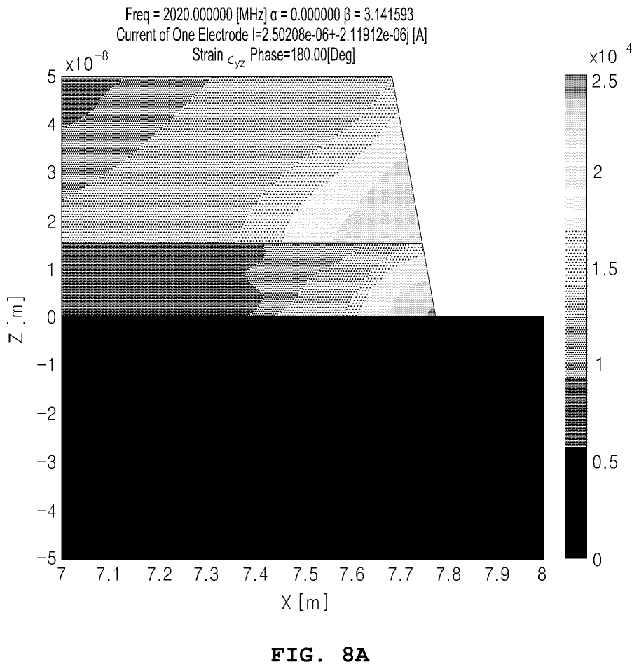

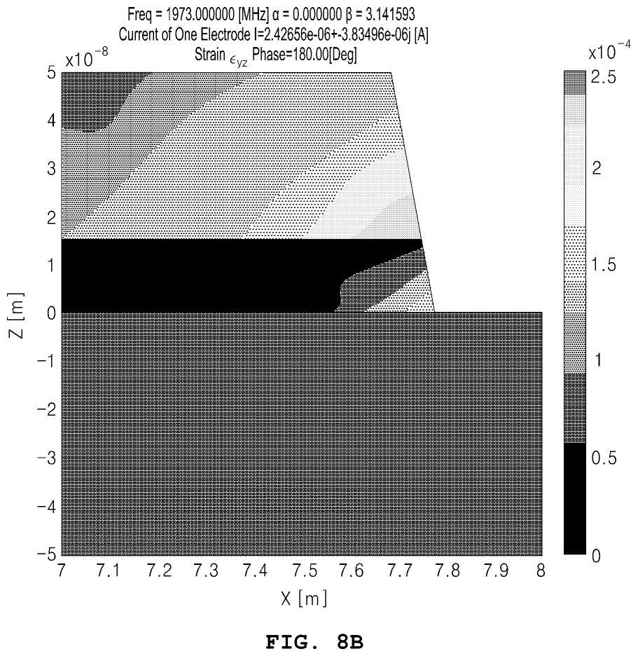

FIG. 8A and FIG. 8B show a comparison of the calculated shear strain results using the surface acoustic wave devices according to the prior art and an embodiment of the present invention.

FIG. 8A and FIG. 8B show the calculated shear strain εyz for the case where the lower electrode contains titanium (FIG. 8A) and for the case where the lower electrode contains tungsten (FIG. 8B). In the figures, smaller strain is represented by darker shades of black, indicating lower strain. As shown in an embodiment of the present invention, when the lower electrode includes tungsten, which has a higher elasticity, the deformation of the lower electrode is relatively small, and as a result, the deformation occurring in the upper electrode 220 made of aluminum-copper alloy is also reduced.

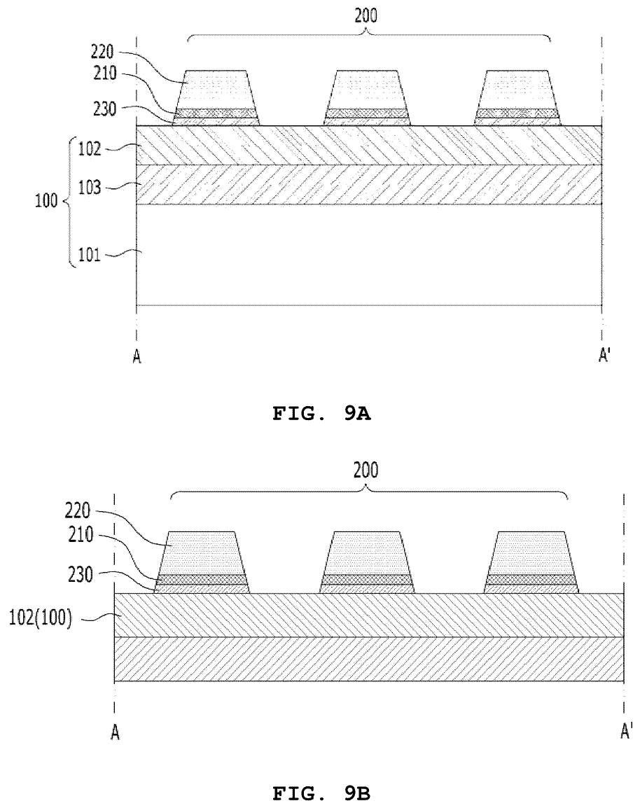

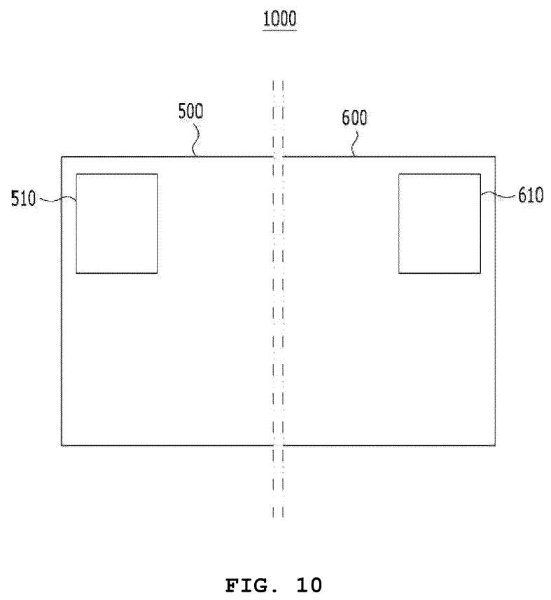

FIG. 9A and FIG. 9B are diagrams illustrating a surface acoustic wave device with an improved nonlinear electrode structure according to another embodiment of the present invention.

Referring to FIG. 9A, the surface acoustic wave device with an improved nonlinear electrode structure according to another embodiment of the present invention may further include a bonding enhancement layer 230 between the lower electrode 210 and the piezoelectric substrate 100.

The bonding enhancement layer 230 may, for example, include titanium or chromium. For instance, when the lower electrode 210 includes tungsten, the bonding enhancement layer 230 may be configured to include titanium or chromium.

The bonding enhancement layer 230 can improve the adhesion between the surface of the piezoelectric substrate 100 and the lower electrode 210. That is, when the lower electrode 210 includes tungsten, the film stress is high, making it prone to delamination from the piezoelectric substrate 100. Therefore, a bonding enhancement layer 230 can be inserted as a buffer to ensure better adhesion of the lower electrode 210 to the piezoelectric layer 102.

The thickness of the bonding enhancement layer 230 may be smaller than the thickness of the lower electrode 210. For example, when the bonding enhancement layer 230 includes titanium, its electrical resistivity is higher than that of tungsten. Therefore, by forming the bonding enhancement layer 230 as thin as possible, the resistance can be reduced.

As shown in FIG. 9B, the piezoelectric substrate 100 may be configured as a single structure of the piezoelectric layer 102, with the support substrate 101 and/or the insert layer 103 omitted.

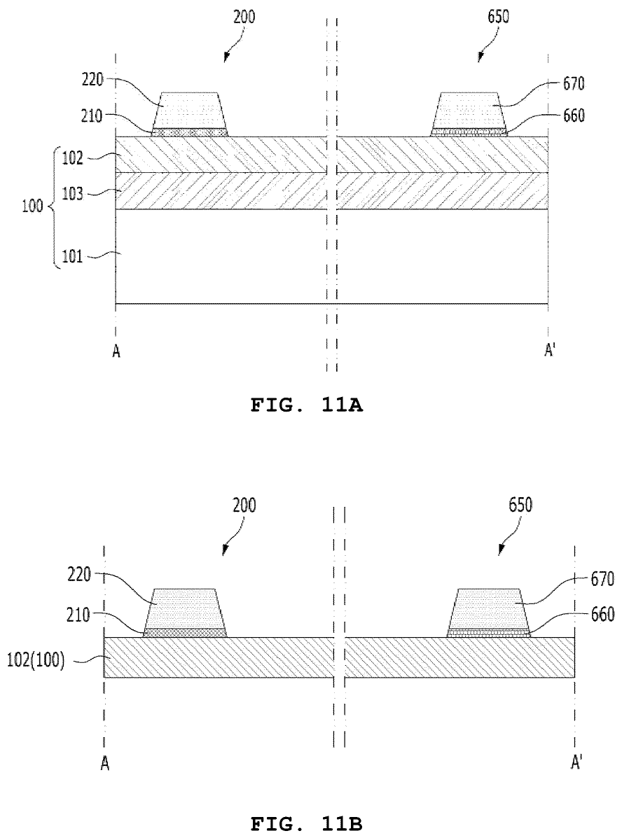

FIGS. 10 to 11B illustrate a filter 1000 comprising a surface acoustic wave device with an improved nonlinear electrode structure according to an embodiment of the present invention.

Referring to FIG. 10, the filter 1000 may include a transmission circuit 500 and a reception circuit 600. The transmission circuit 500 may include a first SAW resonator 510, and the reception circuit 600 may include a second SAW resonator 610. A comparison between the surface acoustic wave devices included in the first SAW resonator 510 and the second SAW resonator 610 will be explained with reference to FIGS. 11A and 11B.

Referring to FIG. 11A, the plurality of IDT electrodes 200 included in the first SAW resonator 510 may include a lower electrode 210 containing tungsten or chromium and an upper electrode 220 containing an aluminum-copper alloy, similar to the IDT electrodes explained using FIG. 2.

On the other hand, the plurality of IDT electrodes 650 included in the second SAW resonator 610 may include a lower electrode 660 containing titanium and an upper electrode 670 containing an aluminum-copper alloy, according to the conventional electrode structure.

That is, when the filter 1000 operates according to the 5G communication standard supporting carrier aggregation at the transmitter (Tx) side, intermodulation caused by two or more transmission signals input to the first SAW resonator 510, which has nonlinearity, can become an issue. Therefore, in the filter 1000 according to an embodiment of the present invention, the lower electrode of the plurality of IDT electrodes in the first SAW resonator 510, included in the transmission circuit 500 supporting carrier aggregation, contains titanium or chromium with high hardness and elasticity, thereby reducing nonlinear operation and suppressing the generation of unnecessary signals.

On the other hand, the filter 1000 according to an embodiment of the present invention may include a piezoelectric substrate 100 consisting of a single structure of the piezoelectric layer 102, as shown in FIG. 11B, where the support substrate 101 and/or the insertion layer 103 are omitted.

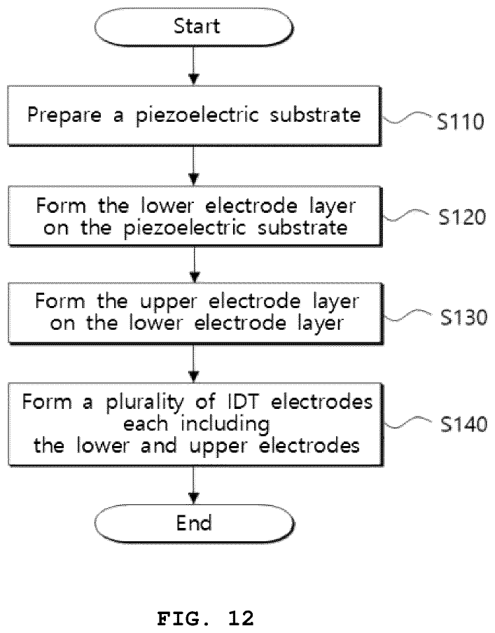

FIG. 12 is a flowchart illustrating the manufacturing method of a surface acoustic wave device with an improved nonlinear electrode structure according to an embodiment of the present invention.

Referring to FIG. 12, the manufacturing method of a surface acoustic wave device according to an embodiment of the present invention includes the steps of preparing a piezoelectric substrate (S110), forming a lower electrode layer on the piezoelectric substrate (S120), forming an upper electrode layer on the lower electrode layer (S130), and forming a plurality of IDT electrodes including a lower electrode and an upper electrode (S140).

First, the step of preparing the piezoelectric substrate (S110) is performed. The piezoelectric substrate 100 may be a single-layer piezoelectric substrate or a laminated structure consisting of one or more substrates. The laminated substrate may, for example, have a structure where a piezoelectric layer is bonded to a supporting substrate such as silicon via an intermediate layer.

In this case, bonding the supporting substrate 101 and the piezoelectric layer 102 may include bonding an intermediate layer partially formed on the supporting substrate 110 with another intermediate layer partially formed on the piezoelectric layer 120.

Next, the step of forming the lower electrode film on the piezoelectric substrate (S120) is carried out. The lower electrode film may include tungsten or chromium and can be formed with a thickness ranging from 5 nm to 20 nm.

Next, the step of forming the upper electrode film on the lower electrode film (S130) is carried out. The upper electrode film may include an aluminum-copper alloy and can completely cover the upper surface of the lower electrode film.

Finally, the step of forming a plurality of IDT electrodes including the lower and upper electrodes (S140) is carried out. For example, a photoresist pattern is formed on the upper electrode film, and the lower and upper electrode films are selectively etched to form the plurality of IDT electrodes.

Alternatively, a photoresist pattern is formed on the piezoelectric substrate 100, and the lower and upper electrode films are deposited. Then, by using a lift-off process, the lower and upper electrode films are selectively removed to form the plurality of IDT electrodes.

Although embodiments of the present invention have been described so far with reference to the accompanying drawings, it will be apparent to those skilled in the art that the present invention may be performed in other forms without departing from the technical spirit or essential characteristics of the present invention. Therefore, the above-described embodiments should be understood as exemplary in all respects and are not limited.

What is claimed is:

1. A surface acoustic wave (SAW) device having an electrode structure with improved nonlinearity, the device comprising:
a piezoelectric substrate; and
a plurality of IDT electrodes formed on the piezoelectric substrate,
wherein each of the plurality of IDT electrodes includes:
a lower electrode formed on a surface of the piezoelectric substrate; and
an upper electrode formed on the lower electrode,
wherein the lower electrode has a hardness of 12 GPa to 16 GPa.

2. The surface acoustic wave device of claim 1, wherein the lower electrode comprises tungsten or chromium, and the upper electrode comprises an aluminum-copper alloy.

3. The surface acoustic wave device of claim 2, wherein the lower electrode has a thickness of 5 nm to 20 nm.

4. The surface acoustic wave device of claim 2, wherein the lower electrode has an elastic modulus of 320 GPa or more.

5. The surface acoustic wave device of claim 1, further comprising a bonding enhancement layer interposed between the lower electrode and the piezoelectric substrate.

6. The surface acoustic wave device of claim 5, wherein the bonding enhancement layer has a thickness smaller than the thickness of the lower electrode.

7. A filter comprising a transmission circuit and a reception circuit,
wherein the transmission circuit comprises a first surface acoustic wave (SAW) resonator,
the reception circuit comprises a second SAW resonator,
the first SAW resonator comprises a plurality of first IDT electrodes,
the second SAW resonator comprises a plurality of second IDT electrodes, and
each of the plurality of first IDT electrodes comprises:
a lower electrode formed on a surface of a piezoelectric substrate; and
an upper electrode formed on the lower electrode,
wherein the lower electrode has a hardness of 12 GPa to 16 GPa.

8. The filter of claim 7, wherein the lower electrode comprises tungsten or chromium, and the upper electrode comprises an aluminum-copper alloy.

9. The filter of claim 8, wherein the lower electrode has a thickness of 5 nm to 20 nm.

10. The filter of claim 8, wherein the lower electrode has an elastic modulus of 320 GPa or more.

11. The filter of claim 7, further comprising a bonding enhancement layer interposed between the lower electrode and the piezoelectric substrate.

12. The filter of claim 11, wherein the bonding enhancement layer has a thickness smaller than the thickness of the lower electrode.

13. A method of manufacturing a surface acoustic wave device having an electrode structure with improved nonlinearity, comprising:
preparing a piezoelectric substrate;
forming a lower electrode film on the piezoelectric substrate;
forming an upper electrode film on the lower electrode film; and
forming a plurality of IDT electrodes comprising a lower electrode and an upper electrode,
wherein the lower electrode has a hardness of 12 GPa to 16 GPa.

14. The method of claim 13, wherein the lower electrode comprises tungsten or chromium, and the upper electrode comprises an aluminum-copper alloy.

15. The method of claim 14, wherein the lower electrode has a thickness of 5 nm to 20 nm.
